(19) United States
(12) Patent Application Publication
(10) Pub. No.: US 2012/0314369 A1
(43) Pub. Date: Dec. 13, 2012

(54) PACKAGE CARRIER AND PACKAGE STRUCTURE

(75) Inventor: Chien-Nan Wu, Taipei (TW)

(73) Assignee: SUBTRON TECHNOLOGY CO. LTD., Hsinchu (TW)

(21) Appl. No.: 13/283,565

(22) Filed: Oct. 27, 2011

(30) Foreign Application Priority Data
Jun. 13, 2011 (TW) 100120569

(51) Int. Cl. H05K 7/20; H05K 1/00

(52) U.S. Cl. 361/701; 174/250; 174/252; 361/760; 361/720

(57) ABSTRACT

A package carrier includes: a carrier having a main mounting surface and at least two side mounting surfaces connecting the main mounting surface; a dielectric layer disposed on the carrier, having multiple first openings and extending from the main mounting surface up, along boundaries between the main mounting surface and the side mounting surfaces, onto the side mounting surfaces, in which the first openings expose a portion of the main mounting surface and portions of the side mounting surfaces; a metal layer disposed on the dielectric layer and having multiple second openings disposed correspondingly to the first openings and multiple third openings exposing the partial dielectric layer at the above-mentioned boundaries; a surface treatment layer disposed on the partial metal layer; and a solder resist layer disposed on a portion of the metal layer and a portion of the dielectric layer both exposed out of the surface treatment layer.

### CROSS-REFERENCE TO RELATED APPLICATION

This application claims the priority benefit of Taiwan application serial no. 100120569, filed on Jun. 13, 2011. The entirety of the above-mentioned patent application is hereby incorporated by reference herein and made a part of this specification.

### BACKGROUND OF THE INVENTION

1. Field of the Invention

The invention generally relates to a package carrier and a package structure, and more particularly, to a package carrier and a package structure with better heat-dissipating effect.

2. Description of Related Art

In terms of currently common light-emitting diode (LED) package structures, the LED chip thereof needs to be packaged prior to usage and a lot of thermal energy is produced by the LED chip during emitting light. If the thermal energy produced by the LED chip is not dissipated and accumulated in the LED package structure, the temperature of the LED package structure may steadily rise. As a result, the LED chip has a decayed luminance and a shorter lifetime due to the above-mentioned over heat, and even more seriously, gets permanent damage. To overcome the problem, a current LED package structure always employs a heat sink for purpose of heat-dissipating of the LED chip.

A conventional package substrate is composed mainly of a plurality of patterned conductive layers and at least an insulation layer, in which the insulation layer is disposed between two adjacent patterned conductive layers to achieve insulation effect. The heat sink is fixed onto a lower surface of the package substrate through an adhesive layer. In general speaking, the LED chip is electrically connected to the package substrate, and the heat produced by the LED chip can be transmitted to the heat sink via the patterned conductive layers and the insulation layer so as to transmit heat by conduction. However, since the heat-conducting rate of the adhesive layer and the insulation layer is poor, during the heat produced by the LED chip is being transmitted to the heat sink via the patterned conductive layers and the insulation layer, the thermal resistance established by the transmitting path would be increased, which results in heat-conducting difficulty.

Moreover, in the prior art, in order to advance the application of LED package structures, a LED package structure is often designed to have light-emitting effect with three-dimensional polyhedron. In this regard, a plurality of package substrates carrying LED chips need to be provided and, through a plurality of circuit substrates connecting the package substrates, the LED package structure can be controlled in series connection, parallel connection or series-parallel connection. It can be seen the quantities of the package substrates and the circuit substrates required by the above-mentioned LED package structure with light-emitting effect with three-dimensional polyhedron are quite many, which results in higher fabrication cost, more difficulty and more complexity of the process with the conventional LED package structure.

### SUMMARY OF THE INVENTION

Accordingly, the invention is directed to a package carrier suitable for carrying a plurality of heat-generating elements.

The invention is also directed to a package structure with better heat-dissipating effect.

The invention provides a package carrier, which includes a carrier, a dielectric layer, a metal layer, a surface treatment layer and a solder resist layer. The carrier has a main mounting surface and at least two side mounting surfaces connecting the main mounting surface. The dielectric layer is disposed on the carrier and has a plurality of first openings. The dielectric layer extends from the main mounting surface up, along boundaries between the main mounting surface and the side mounting surfaces, onto the side mounting surfaces. The first openings expose a portion of the main mounting surface and portions of the side mounting surfaces. The metal layer is disposed on the dielectric layer and has a plurality of second openings and a plurality of third openings. The second openings are disposed correspondingly to the first openings, and the third openings expose a portion of the dielectric layer located at the boundaries between the main mounting surface and the side mounting surfaces. The surface treatment layer is disposed on a portion of the metal layer. The solder resist layer is disposed on a portion of the metal layer and a portion of the dielectric layer both are exposed out of the surface treatment layer.

In an embodiment of the invention, the above-mentioned carrier includes a heat sink, a heat-dissipating fin, a thermal tube or a vapor chamber heat block.

In an embodiment of the invention, the above-mentioned carrier includes a supporting element and a heat-conductive layer, in which the supporting element has the main mounting surface and the side mounting surfaces, the heat-conductive layer covers the main mounting surface and the side mounting surfaces, and the first openings of the dielectric layer expose a portion of the heat-conductive layer.

In an embodiment of the invention, the above-mentioned supporting element includes a plastic supporting frame, a heat sink, a heat-dissipating fin, a thermal tube or a vapor chamber heat block.

In an embodiment of the invention, the above-mentioned package carrier further includes a first adhesive layer disposed between the heat-conductive layer and the dielectric layer, in which the first adhesive layer extends from the heat-conductive layer located on the main mounting surface up, along an upper place of the boundaries between the main mounting surface and the side mounting surfaces, onto the heat-conductive layer located on the side mounting surfaces.

In an embodiment of the invention, the above-mentioned carrier further includes a laminated structure disposed between the heat-conductive layer and the supporting element, in which the laminated structure includes a second adhesive layer, a first conductive layer, a second conductive layer, an insulation layer and a plurality of conductor pillars, the second adhesive layer is disposed between the first conductive layer and the heat-conductive layer, the insulation layer is located between the first conductive layer and the second conductive layer and has a plurality of through holes, and the conductor pillars are respectively disposed in the through holes and connected to the first conductive layer and the second conductive layer.

In an embodiment of the invention, the above-mentioned package carrier further includes an adhesive layer disposed between the carrier and the dielectric layer, in which the adhesive layer extends from the main mounting surface of the carrier up, along the boundaries between the main mounting surface and the side mounting surfaces, onto the side mounting surfaces.

The invention also provides a package structure, which includes a package carrier, a plurality of heat-generating elements, a plurality of bonding wires and a plurality of package bodies. The package carrier includes a carrier, a dielectric layer, a metal layer, a surface treatment layer and a solder resist layer. The carrier has a main mounting surface and at least two side mounting surfaces connecting the main mounting surface. The dielectric layer is disposed on the carrier and has a plurality of first openings, in which the dielectric layer extends from the main mounting surface up, along boundaries between the main mounting surface and the side mounting surfaces, onto the side mounting surfaces, and the first openings expose a portion of the main mounting surface and portions of the side mounting surfaces. The metal layer is disposed on the dielectric layer and has a plurality of second openings and a plurality of third openings. The second openings are disposed correspondingly to the first openings, and the third openings expose a portion of the dielectric layer located at the boundaries between the main mounting surface and the side mounting surfaces. The surface treatment layer is disposed on a portion of the metal layer. The solder resist layer is disposed on a portion of the metal layer and a portion of the dielectric layer both are exposed out of the surface treatment layer. The heat-generating elements are disposed on the package carrier and located on a portion of the main mounting surface and portions of the side mounting surfaces exposed by the first openings. The bonding wires are electrically connected to the heat-generating elements and the package carrier. The package bodies encapsulate the heat-generating elements, the bonding wires and a portion of the package carrier and expose a portion of the solder resist layer and a portion of the dielectric layer located on boundaries between the main mounting surface and the side mounting surfaces.

In an embodiment of the invention, the electrical connection between the above-mentioned heat-generating elements and the package carrier includes connection in series, connection in parallel or connection in series-and-parallel.

In an embodiment of the invention, the above-mentioned carrier includes a heat sink, a heat-dissipating fin, a thermal tube or a vapor chamber heat block.

In an embodiment of the invention, the above-mentioned carrier includes a supporting element and a heat-conductive layer, in which the supporting element has the main mounting surface and the side mounting surfaces, the heat-conductive layer covers the main mounting surface and the side mounting surfaces, and the first openings of the dielectric layer expose a portion of the heat-conductive layer.

In an embodiment of the invention, the above-mentioned supporting element includes a plastic supporting frame, a heat sink, a heat-dissipating fin, a thermal tube or a vapor chamber heat block.

In an embodiment of the invention, the above-mentioned package carrier further includes a first adhesive layer disposed between the heat-conductive layer and the dielectric layer, in which the first adhesive layer extends from the heat-conductive layer located on the main mounting surface up, along an upper place of the boundaries between the main mounting surface and the side mounting surfaces, onto the heat-conductive layer located on the side mounting surfaces.

In an embodiment of the invention, the above-mentioned carrier further includes a laminated structure disposed between the heat-conductive layer and the supporting element. The laminated structure includes a second adhesive layer, a first conductive layer, a second conductive layer, an insulation layer and a plurality of conductor pillars. The second adhesive layer is disposed between the first conductive layer and the heat-conductive layer, the insulation layer is located between the first conductive layer and the second conductive layer and has a plurality of through holes, and the conductor pillars are respectively disposed in the through holes and connected to the first conductive layer and the second conductive layer.

In an embodiment of the invention, the above-mentioned package carrier further includes an adhesive layer disposed between the carrier and the dielectric layer, in which the adhesive layer extends from the main mounting surface of the carrier up, along the boundaries between the main mounting surface and the side mounting surfaces, onto the side mounting surfaces.

Based on the depiction above, the design of the package carrier in the invention features that the dielectric layer extends from the main mounting surface of the carrier up, along boundaries between the main mounting surface and the side mounting surfaces, onto the side mounting surfaces by using the flexibility property thereof, and the heat-generating elements are located on a portion of the main mounting surface and portions of the side mounting surfaces of the carrier exposed by the first openings of the dielectric layer. In this way, when the heat-generating elements are, for example, a plurality of LED chips, the package structure of the invention can have light-emitting effect with three-dimensional polyhedron. In addition, the heat of the heat-generating elements can be directly and fast transmitted outwards through the carrier, so that the package structure of the invention has better heat-dissipating effect.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional diagram of a package carrier according to an embodiment of the invention.

FIG. 2 is a cross-sectional diagram of a package carrier according to another embodiment of the invention.

FIG. 3 is a cross-sectional diagram of a package carrier according to yet another embodiment of the invention.

FIG. 4 is a cross-sectional diagram of a package structure according to an embodiment of the invention.

FIG. 5 is a cross-sectional diagram of a package structure according to another embodiment of the invention.

FIG. 6 is a cross-sectional diagram of a package structure according to yet another embodiment of the invention.

FIG. 7 is a cross-sectional diagram of a package structure according to yet another embodiment of the invention.

FIG. 8 is a cross-sectional diagram of a package structure according to yet another embodiment of the invention.

FIG. 9 is a cross-sectional diagram of a package structure according to yet another embodiment of the invention.

FIG. 10 is a cross-sectional diagram of a package structure according to yet another embodiment of the invention.

FIG. 11 is a cross-sectional diagram of a package structure according to yet another embodiment of the invention.

FIGS. 12A and 12B are respectively a top-view schematic diagram and a three-dimensional schematic diagram of a package structure according to an embodiment of the invention.

FIGS. 13A and 13B are respectively a top-view schematic diagram and a three-dimensional schematic diagram of a package structure according to another embodiment of the invention.

### DESCRIPTION OF THE EMBODIMENTS

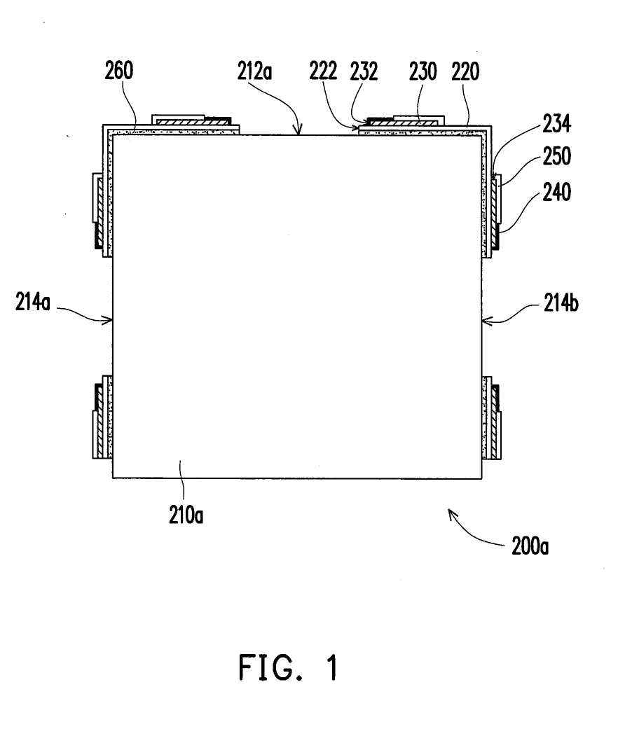

FIG. 1 is a cross-sectional diagram of a package carrier according to an embodiment of the invention. Referring to FIG. 1, in the embodiment, a package carrier 200a includes a carrier 210a, a dielectric layer 220, a metal layer 230, a surface treatment layer 240 and a solder resist layer 250. In more details, the carrier 210a has a main mounting surface 212a and at least two side mounting surfaces 214a and 214b connecting the main mounting surface 212a, in which the carrier 210a is, for example, a heat sink, a heat-dissipating fin, a thermal tube or a vapor chamber heat block. The carrier 210a herein is a heat sink as an example.

The dielectric layer 220 is disposed on the carrier 210a and has a plurality of first openings 222. In the embodiment, the package carrier 200a further includes an adhesive layer 260, and the dielectric layer 220 is adhered onto the carrier 210a through the adhesive layer 260, in which the dielectric layer 220 and the adhesive layer 260 are conformingly disposed. In particular, the dielectric layer 220 of the embodiment extends from the main mounting surface 212a of the carrier 210a up, along boundaries between the main mounting surface 212a and the side mounting surfaces 214a and 214b, onto the side mounting surfaces 214a and 214b, and the first openings 222 expose a portion of the main mounting surface 212a and portions of the side mounting surfaces 214a and 214b of the carrier 210a. The material of the dielectric layer 220 is, for example, polyimide (PI), liquid crystal polymer (LCP), polyethyleneimine (PEI), polyethylene naphthalate (PEN) or polyethylene terephthalate (PET).

The metal layer 230 is disposed on the dielectric layer 220 and has a plurality of second openings 232 and a plurality of third openings 234, in which the second openings 232 of the metal layer 230 are disposed correspondingly to the first openings 222 and the third openings 234 expose a portion of the dielectric layer 220 located at the boundaries between the main mounting surface 212a and the side mounting surfaces 214a and 214b of the carrier 210a. In addition, the diameter of the second openings 232 of the metal layer 230 in the embodiment is substantially greater than or equal to the diameter of the first openings 222 of the dielectric layer 220. In FIG. 1, the diameter of the second openings 232 of the metal layer 230 is, as an example, substantially greater than the diameter of the first openings 222 of the dielectric layer 220. The metal layer 230 is, for example, copper layer or aluminium layer. The surface treatment layer 240 is disposed on a portion of the metal layer 230, in which the material of the surface treatment layer 240 is, for example, nickel, gold, silver, nickel-gold, nickel-silver, nickel porpezite or other appropriate metal materials. The solder resist layer 250 is disposed on a portion of the metal layer 230 and a portion of the dielectric layer 220 both are exposed out of the surface treatment layer 240.

Since the material of the dielectric layer 220 in the embodiment is a flexible material, for example, polyimide (PI), liquid crystal polymer (LCP), polyethyleneimine (PEI), polyethylene naphthalate (PEN) or polyethylene terephthalate (PET), so that the dielectric layer 220 is flexible and can extend from the main mounting surface 212a of the carrier 210a up, along boundaries between the main mounting surface 212a and the side mounting surfaces 214a and 214b, onto the side mounting surfaces 214a and 214b. In this way, the package carrier 200a of the embodiment can be bent into a package carrier with three-dimensional form by using the flexibility property of the dielectric layer 220.

It should be noted that the notations and partial content in the above-mentioned embodiment are continuously used, in which the same notations represent the same as or similar to the above-mentioned embodiment, while the same depictions are omitted and can be understood referring to the above-mentioned embodiment.

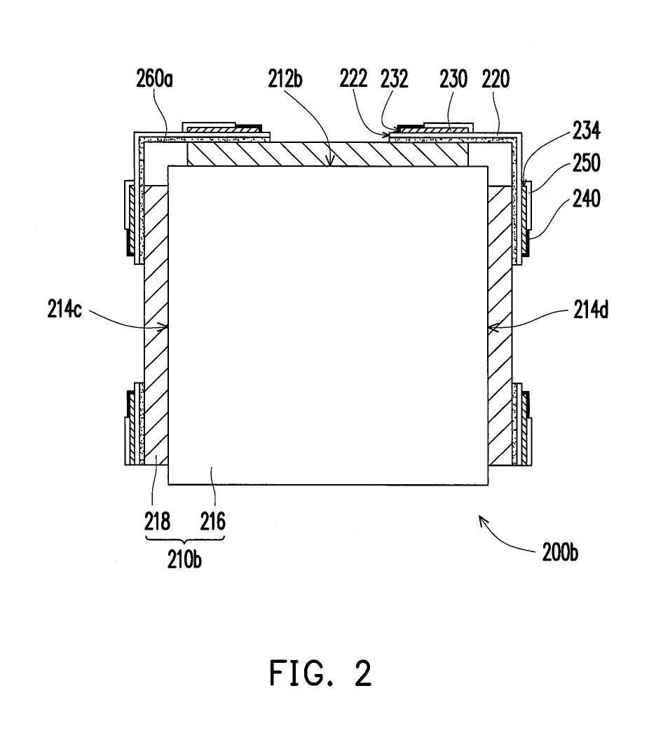

FIG. 2 is a cross-sectional diagram of a package carrier according to another embodiment of the invention. Referring to FIG. 2, a package carrier 200b of the embodiment is similar to the package carrier 200a of FIG. 1, except that the carrier 210b of the package carrier 200b in FIG. 2 is composed of a supporting element 216 and a heat-conductive layer 218. In more details, the supporting element 216 has a main mounting surface 212b and a plurality of side mounting surfaces 214c and 214d connecting the main mounting surface 212b. The heat-conductive layer 218 is disposed on and covers the main mounting surface 212b and the side mounting surfaces 214c and 214d. The heat-conductive layer 218 merely covers a portion of the main mounting surface 212b and portions of the side mounting surfaces 214c and 214d. Namely, the heat-conductive layer 218 would expose a portion of the main mounting surface 212b and portions of the side mounting surfaces 214c and 214d. In other unshown embodiments however, the heat-conductive layer 218 can entirely overlay the main mounting surface 212b and the side mounting surfaces 214c and 214d.

The first openings 222 of the dielectric layer 220 expose a portion of the heat-conductive layer 218. The supporting element 216 herein is, for example, a plastic supporting frame, a heat sink, a heat-dissipating fin, a thermal tube or a vapor chamber heat block, The material of the heat-conductive layer 218 is, for example, a conductive material such as copper, aluminium, other appropriate materials, or a nonconductive material such as aluminium oxide, aluminium nitride, graphite or other appropriate nonconductive materials. In addition, the adhesive layer 260a of the package carrier 210b in the embodiment is disposed between the heat-conductive layer 218 and the dielectric layer 220, in which the adhesive layer 260a extends from the heat-conductive layer 218 located on the main mounting surface 212b up, along an upper place of the boundaries between the main mounting surface 212b and the side mounting surfaces 214c and 214d, onto the heat-conductive layer 218 located on the side mounting surfaces 214c and 214d.

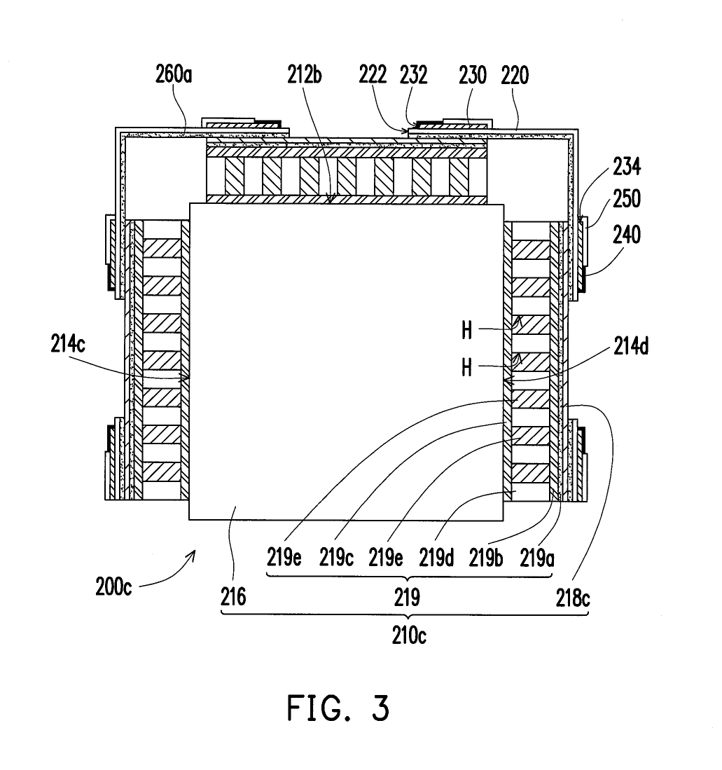

FIG. 3 is a cross-sectional diagram of a package carrier according to yet another embodiment of the invention. Referring to FIG. 3, in order to enhance the heat-dissipating effect of the package carrier 200b, the embodiment provides yet another package carrier 200c. The package carrier 200c of the embodiment is similar to the package carrier 200b of FIG. 2, except that the carrier 210c of the package carrier 200c in FIG. 3 is composed of a supporting element 216, a heat-conductive layer 218c and a laminated structure 219, in which the laminated structure 219 is disposed between the heat-conductive layer 218c and the supporting element 216. In more details, the laminated structure 219 includes an adhesive layer 219a, a first conductive layer 219b, a second conductive layer 219c, an insulation layer 219d and a plurality of conductor pillars 219e. The adhesive layer 219a is disposed between the first conductive layer 219b and the heat-conductive layer 218c, in which the adhesive layer 219a is, for example, a resin layer, a silver epoxy layer, a plating copper layer or a chemical copper layer. The insulation layer 219d is located between the first conductive layer 219b and the second conductive layer 219c and has a plurality of through holes H. The conductor pillars 219e are respectively disposed in the through holes H and connected to the first conductive layer 210b and the second conductive layer 219c. The carrier 210c of the embodiment further has the laminated structure 219, so that the heat-dissipating effect of the package carrier 200c can be effectively advanced.

It should be noted that in other unshown embodiments, an unbent package carrier may not need to employ a supporting element. That is to say, the carrier of the package carrier can be a heat-conductive layer, and a dielectric layer, a metal layer, a surface treatment layer and a solder resist layer are sequentially stacked on the heat-conductive layer in the above-mentioned way, which still belongs to the technical scheme and falls in the claimed scope of the invention.

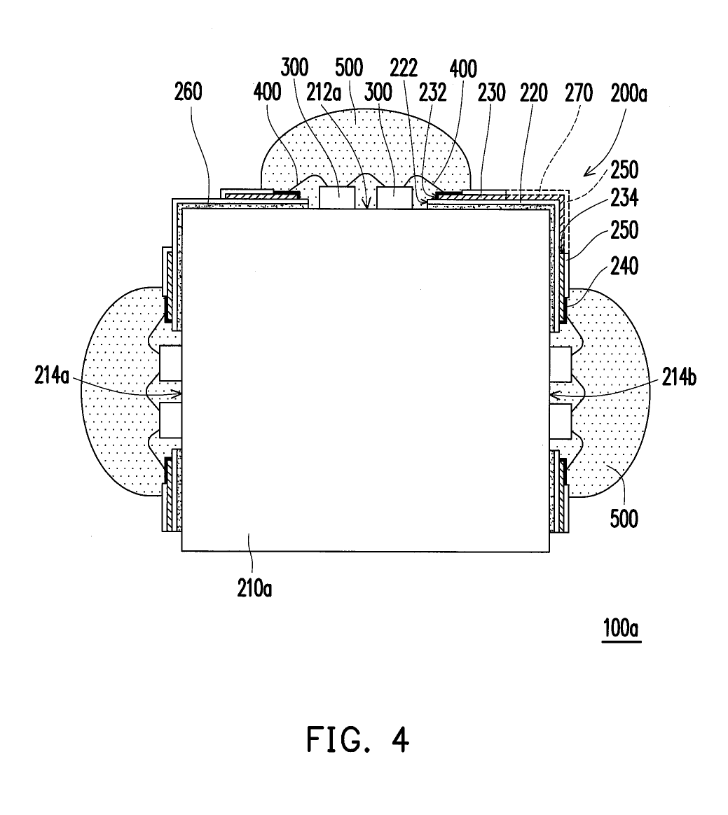

FIG. 4 is a cross-sectional diagram of a package structure according to an embodiment of the invention. Referring to FIG. 4, in the embodiment, a package structure 100a includes a package carrier 200a of FIG. 1, a plurality of heat-generating elements 300, a plurality of bonding wires 400 and a plurality of package bodies 500. In more details, the heat-generating elements 300 are disposed on the package carrier 200a and located on a portion of the main mounting surface 212a and portions of the side mounting surfaces 214a and 214b of the carrier 210a exposed by the first openings 222 of the dielectric layer 220. The heat-generating elements 300 are, for example, a plurality of electronic chips or a plurality of photoelectric components, which the invention is not limited to. For example, the electronic chip can be an IC chip such as a graphic chip, a memory chip, a semiconductor chip, and the above-mentioned chips can be a single chip or a chip module. The photoelectric component can be, for example, an LED, a laser diode or a gas discharge light source. The heat-generating elements 300 herein are a plurality of LEDs as an example.

The bonding wires 400 are electrically connected to the heat-generating elements 300 and the surface treatment layer 240 of the package carrier 200a. The package bodies 500 encapsulate the heat-generating elements 300, the bonding wires 400 and a portion of the package carrier 200a and expose a portion of the solder resist layer 250 and a portion of the dielectric layer 220 located on the boundaries between the main mounting surface 212a and the side mounting surfaces 214a and 214b of the carrier 210a. In particular, for example, the heat-generating elements 300 located on the main mounting surface 212a of the carrier 210a in the embodiment can connect the metal layer 230 located on the main mounting surface 212a and the side mounting surface 214b through a metallic wiring layer 270 and then connect in series, in parallel or in series-and-parallel the heat-generating elements 300 located on the side mounting surface 214b. In addition, a solder resist layer 250 or a surface treatment layer 240 can be employed and disposed on the metallic wiring layer 270 to protect the metallic wiring layer 270 from being oxidized. In FIG. 4, only a solder resist layer 250 on the metallic wiring layer 270 is schematically shown up.

Since the dielectric layer 220 in the embodiment is flexible and can extend from the main mounting surface 212a of the carrier 210a up, along boundaries between the main mounting surface 212a and the side mounting surfaces 214a and 214b, onto the side mounting surfaces 214a and 214b, the package carrier 200a of the embodiment can be bent into a package carrier with three-dimensional form by using the flexibility property of the dielectric layer 220. In addition, since the heat-generating elements 300 of the embodiment are located on a portion of the main mounting surface 212a and portions of the side mounting surfaces 214a and 214b of the carrier 210a exposed by the first openings 222 of the dielectric layer 220 of the package carrier 200a and the heat-generating elements 300 are electrically connected to the surface treatment layer 240 of the package carrier 200a through the bonding wires 400, the package structure 100a of the embodiment has light-emitting effect with three-dimensional polyhedron.

The heat produced by the heat-generating elements 300 in the embodiment can be directly and fast transmitted outwards, so that the package structure 100a of the embodiment has better heat-dissipating efficiency. A user can dispose the metallic wiring layer 270 on the dielectric layer 220 so as to connect in series, in parallel or in series-and-parallel the heat-generating elements 300 located on the main mounting surface 212a and the side mounting surface 214b by oneself according to the application need, which can advance the application and the flexibility of the package structure 100a.

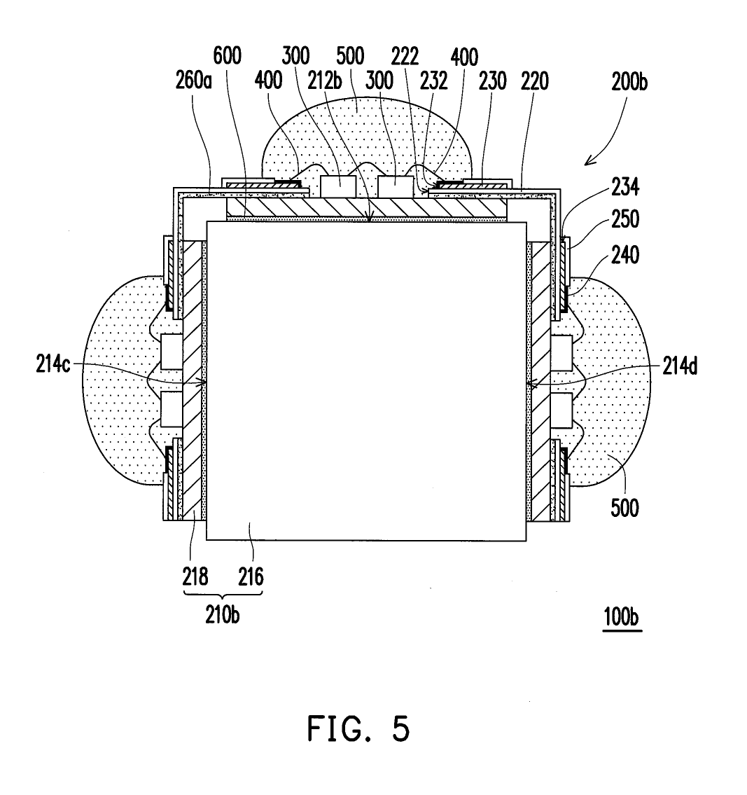

FIG. 5 is a cross-sectional diagram of a package structure according to another embodiment of the invention. Referring to FIG. 5, a package structure 100b of the embodiment is similar to the package structure 100a of FIG. 4, except that the package structure 100b of FIG. 5 adopts a package carrier 200b of FIG. 2, in which the heat-generating elements 300 are disposed on a portion of the heat-conductive layer 218 exposed by the first openings 222 of the dielectric layer 220. In addition, in order to enhance the bonding strength between the heat-conductive layer 218 and the supporting element 216 and increase the heat-dissipating effect of the heat-generating elements 300, the heat-conductive layer 218 can be also adhered to the main mounting surface 212b and the side mounting surfaces 214c and 214d of the supporting element 216 though a heat-conductive glue 600, and the heat produced by the heat-generating elements 300 can be directly and fast transmitted outwards through the heat-conductive layer 218, the heat-conductive glue 600 and the supporting element 216 so as to further advance the heat-dissipating efficiency of the package structure 100b.

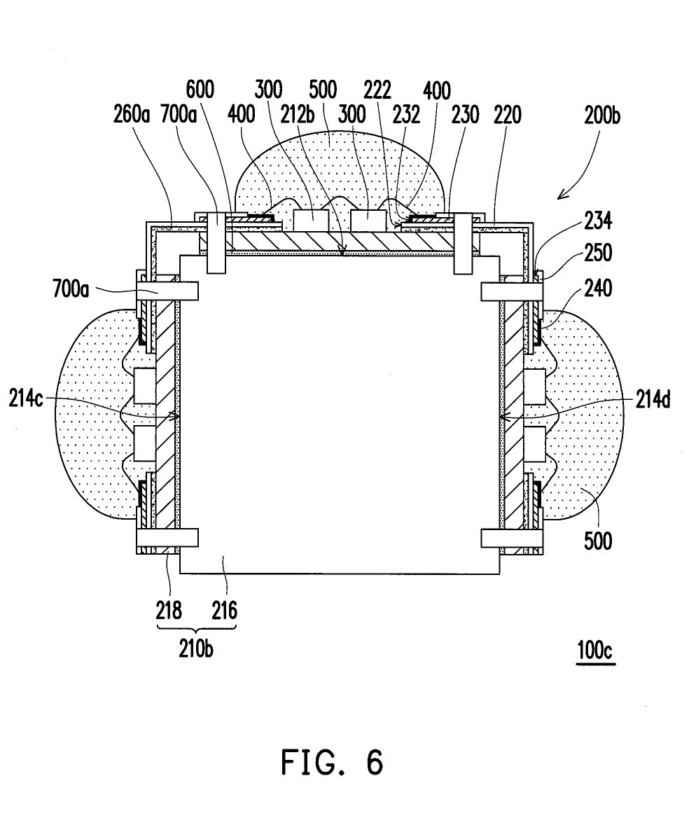

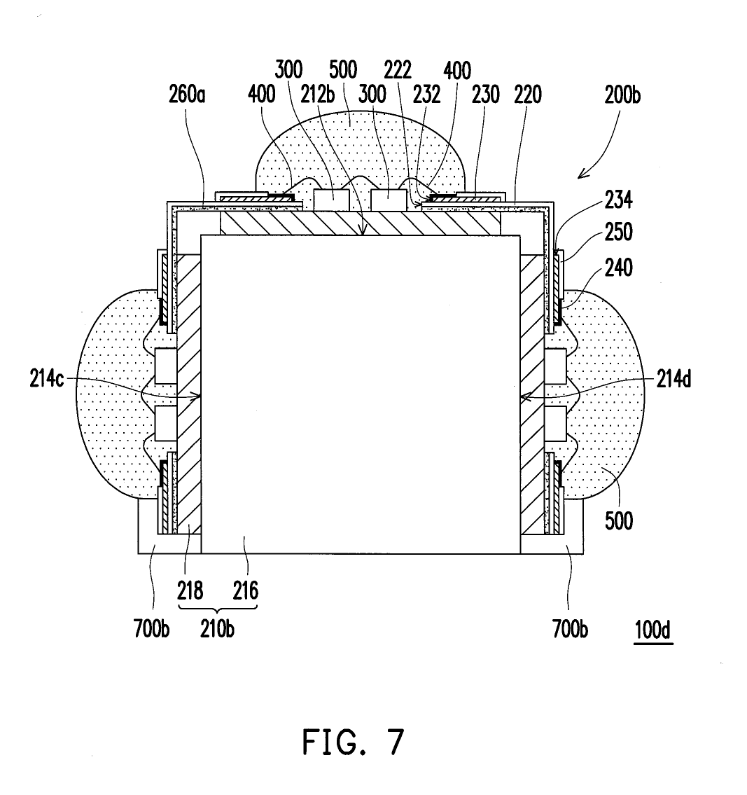

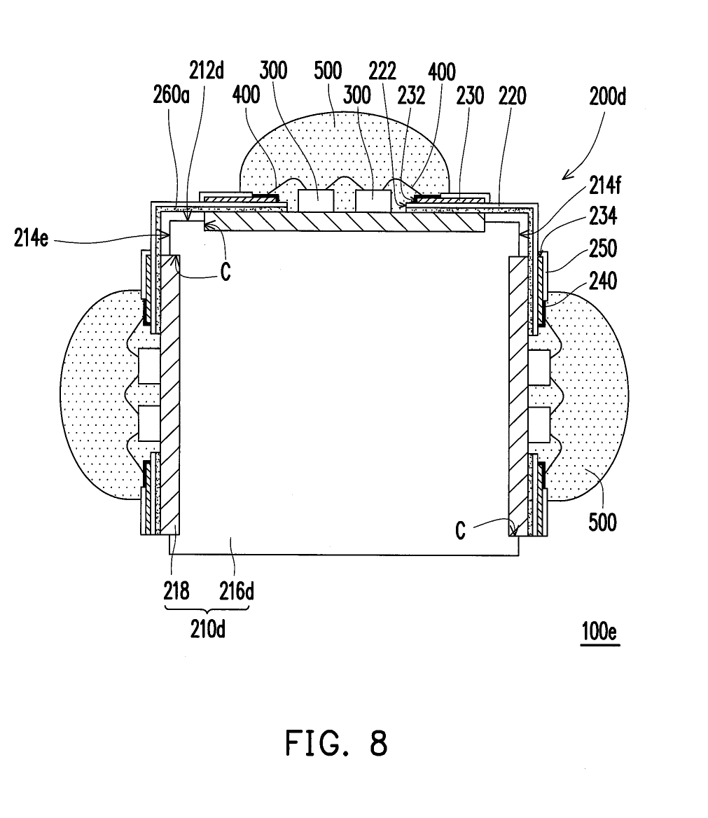

In other embodiments, the bonding strength between the heat-conductive layer 218 and the supporting element 216 can be enhanced in other methods. For example, referring to FIG. 6, which is a cross-sectional diagram of a package structure according to yet another embodiment of the invention, in a package structure 100c of the embodiment, a plurality of fasteners 700a are used and, from the solder resist layer 250, sequentially go through the metal layer 230, the dielectric layer 220, the adhesive layer 260a and the heat-conductive layer 218 to be fastened in the supporting element 216. The fasteners 700a herein are, for example, a plurality of screws or bolts. The bonding strength can be enhanced in another way, referring to FIG. 7, which is a cross-sectional diagram of a package structure according to yet another embodiment of the invention. In a package structure 100d of the embodiment of FIG. 7, a plurality of tenons 700b are used to lock the heat-conductive layer 218 and the adhesive layer 260a, the dielectric layer 220, the metal layer 230 and the solder resist layer 250 located on the heat-conductive layer 218 onto the supporting element 216. The bonding strength can be enhanced in yet another way, referring to FIG. 8, which is a cross-sectional diagram of a package structure according to yet another embodiment of the invention. In a package structure 100e of the embodiment of FIG. 8, a package carrier 200d is similar to the package carrier 200b of FIG. 2, except that the supporting element 216d of the package carrier 200d in the embodiment has a plurality of recesses C, in which the recesses C are located on the main mounting surface 212d and the side mounting surfaces 214e and 214f, while the heat-conductive layer 218 is embedded in the recesses C and fixed on the supporting element 216. In short, the method of enhancing the bonding strength between the heat-conductive layer 218 and the supporting element 216 in FIG. 5 is an example, which the invention is not limited to.

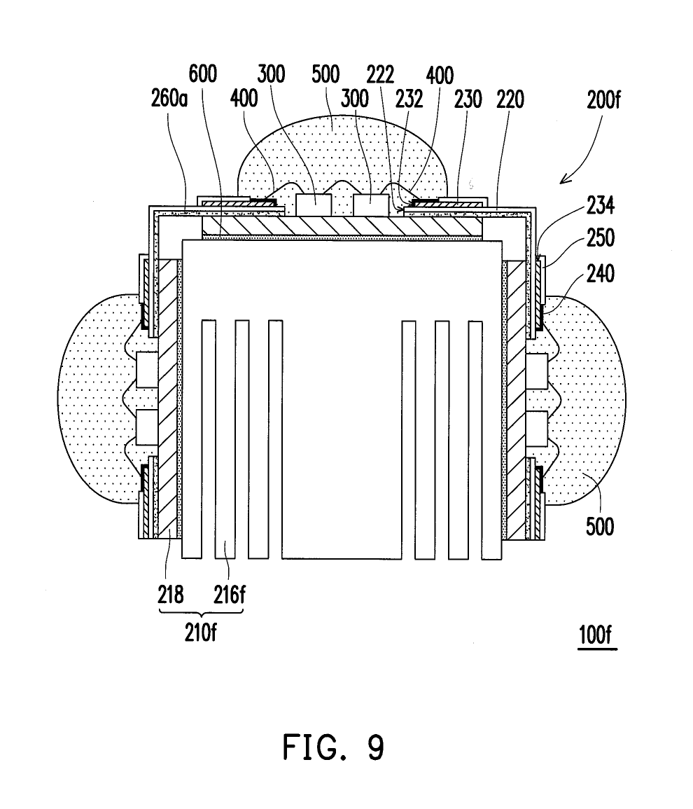

FIG. 9 is a cross-sectional diagram of a package structure according to yet another embodiment of the invention. Referring to FIG. 9, a package structure 100f of the embodiment is similar to the package structure 100b of FIG. 5, except that in the package carrier 200f adopted by the package structure 100f in FIG. 9, the supporting element 216f of the carrier 210f is, for example, a heat-dissipating fin, and the heat produced by the heat-generating elements 300 in the embodiment can be directly and fast transmitted outwards through the heat-conductive layer 218 and the supporting element 216f, so that the heat-dissipating efficiency of the package structure 100f can be effectively advanced.

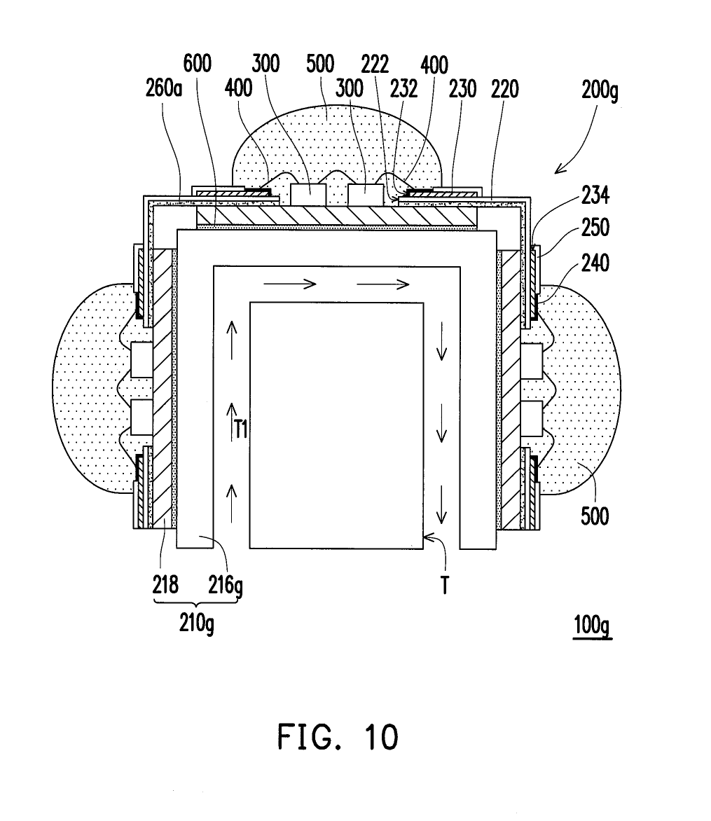

FIG. 10 is a cross-sectional diagram of a package structure according to yet another embodiment of the invention. Referring to FIG. 10, a package structure 100g of the embodiment is similar to the package structure 100b of FIG. 5, except that in the package carrier 200g adopted by the package structure 100g in FIG. 10, the supporting element 216g of the carrier 210g is, for example, a thermal tube, in which the supporting element 216g has a fluid channel T. When the heat produced by the heat-generating elements 300 directly enters the supporting element 216g through the heat-conductive layer 218, an external fluid (for example, gas or liquid, and the flowing direction of the fluid is shown by an arrow direction T1 in FIG. 10) would flow through the fluid channel T to bring away the heat produced by the heat-generating elements 300, so that the heat-dissipating efficiency of the package structure 100g can be effectively advanced.

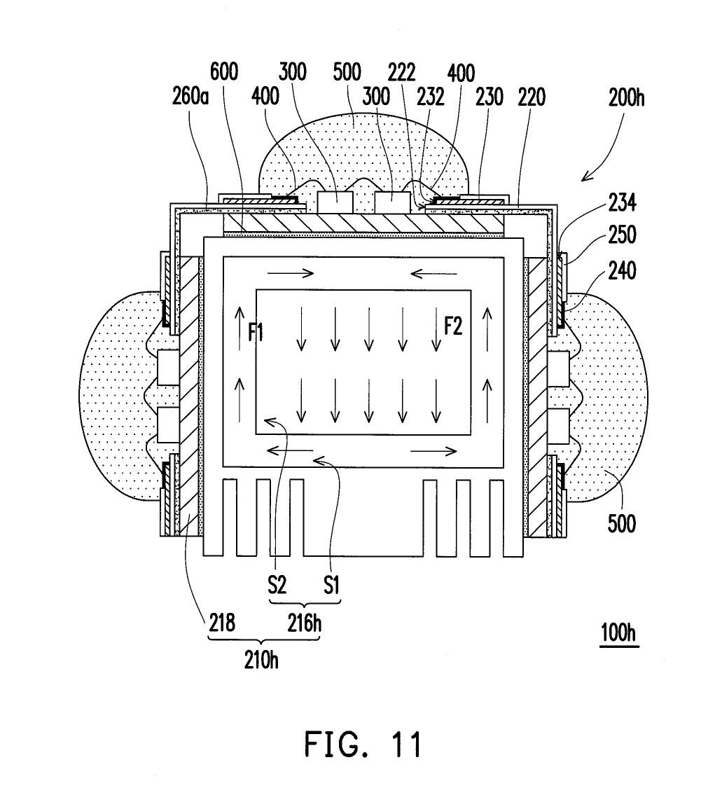

FIG. 11 is a cross-sectional diagram of a package structure according to yet another embodiment of the invention. Referring to FIG. 11, a package structure 100h of the embodiment is similar to the package structure 100b of FIG. 5, except that in the package carrier 200h adopted by the package structure 100h in FIG. 11, the supporting element 216h of the carrier 210h is, for example, a vapour chamber heat block, in which the supporting element 216h has a liquid space S1 and a gas space S2. When the heat produced by the heat-generating elements 300 directly enters the supporting element 216h through the heat-conductive layer 218, the liquid would flow cyclically in the liquid space S1 (the flowing direction of the fluid is shown by an arrow direction F1 in FIG. 11), in which a portion of the liquid would be converted into gas to enter the gas space S2 due to high temperature (the flowing direction of the gas is shown by an arrow direction F2 in FIG. 11). After that, the gas in the gas space S2 would be converted back into liquid due to fall of temperature and enter the liquid space S1 again. Through the above-mentioned cycle between the liquid and the gas, the heat produced by the heat-generating elements 300 can be effectively and fast brought away, so that the heat-dissipating efficiency of the package structure 100h can be effectively advanced.

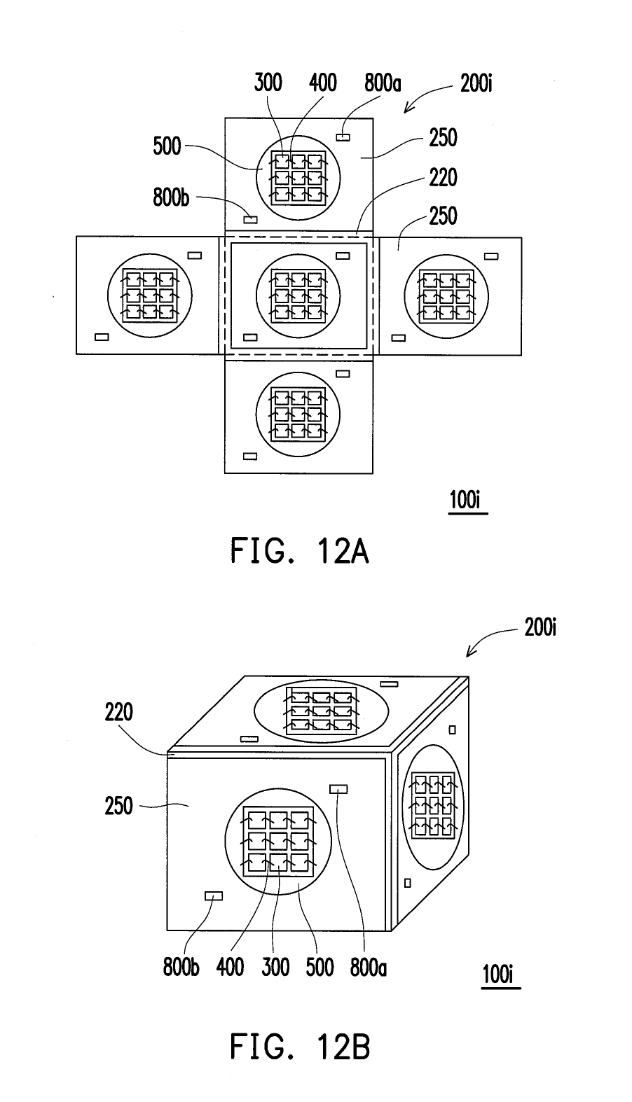

FIGS. 12A and 12B are respectively a top-view schematic diagram and a three-dimensional schematic diagram of a package structure according to an embodiment of the invention. It should be noted that partial elements are omitted in FIGS. 12A and 12B for depiction convenience. In addition, the notations and partial content in the above-mentioned embodiment are continuously used, in which the same notations represent the same as or similar to the above-mentioned embodiment, while the same depictions are omitted and can be understood referring to the above-mentioned embodiment.

Referring to FIGS. 12A and 12B, since the material of the dielectric layer 220 in the embodiment is a flexible material, for example, polyimide (PI), liquid crystal polymer (LCP), polyethyleneimine (PEI), polyethylene naphthalate (PEN) or polyethylene terephthalate (PET), so that the dielectric layer 220 can be bent along the dotted line in FIG. 12A to form a package carrier 200i with three-dimensional shape (for example, rectangular cuboid or cube) as shown in FIG. 12B. After the heat-generating elements 300 (for example, LED chips) are disposed on the package carrier 200i, a package structure 100i in three-dimensional polyhedron shape is formed, and the package structure 100i has a light-emitting effect of three-dimensional polyhedron. In addition, a plurality of solder pads 800a and 800b are disposed on the package carrier 200i, in which the solder pads 800a and 800b are electrically connected to the metal layer 230 (FIG. 2) and an external circuit (not shown) can drive the heat-generating elements 300 through the solder pads 800a and 800b.

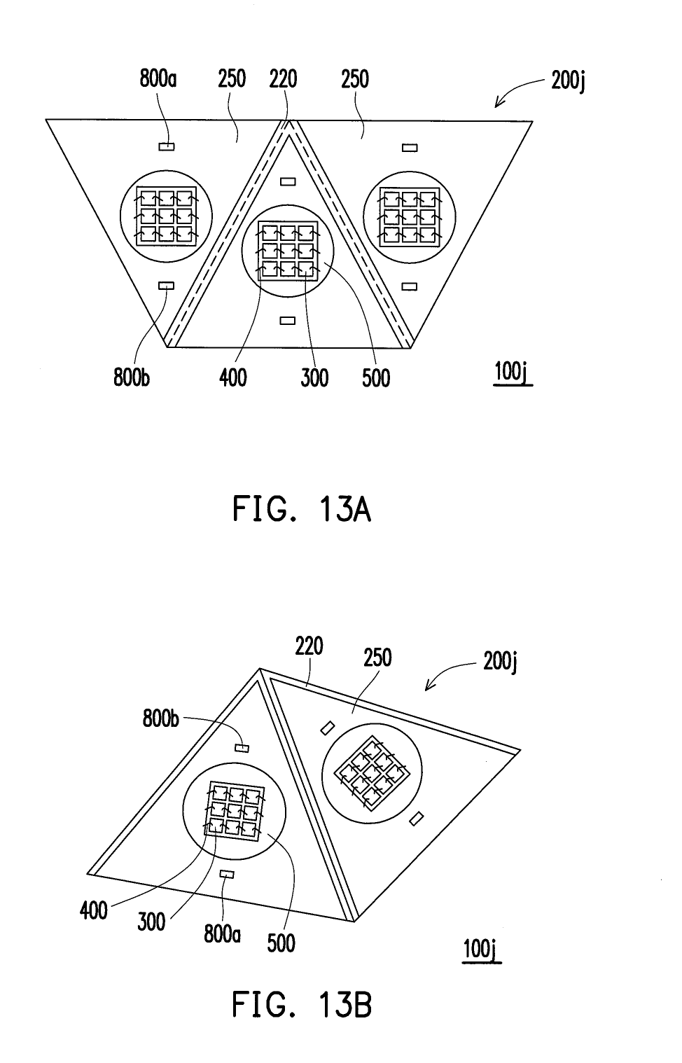

FIGS. 13A and 13B are respectively a top-view schematic diagram and a three-dimensional schematic diagram of a package structure according to another embodiment of the invention. It should be noted that partial elements are omitted in FIGS. 13A and 13B for depiction convenience. In addition, the notations and partial content in the above-mentioned embodiment are continuously used, in which the same notations represent the same as or similar to the above-mentioned embodiment, while the same depictions are omitted and can be understood referring to the above-mentioned embodiment.

Referring to FIGS. 13A and 13B, a package structure 100j of the embodiment is similar to the package structure 100i of the above-mentioned embodiment, except that the three-dimensional package carrier 200j in FIG. 13B has different shape from the three-dimensional package carrier 200i of FIG. 12B. In more details, the dielectric layer 220 can be bent along the dotted line in FIG. 13A to form a package carrier 200j with three-dimensional shape (for example, pyramid) as shown in FIG. 13B. After the heat-generating elements 300 (for example, LED chips) are disposed on the package carrier 200i, a package structure 100j in three-dimensional polyhedron shape is formed, and the package structure 100j has a light-emitting effect of three-dimensional polyhedron.

It should be noted that the invention does not limit the shape of the three-dimensional package carriers 200i and 200j formed after bending the dielectric layer 220. Although the above-mentioned three-dimensional package carriers 200i and 200j can be rectangular cuboid, cube or pyramid, but other known three-dimensional structure designs formed in the same way of bending the dielectric layer 220 by using the flexible property thereof still belong to the technical scheme and still falls in the claimed scope by the invention.

In addition, in other unshown embodiments, any people skilled in the art can, referring to the above-mentioned depiction, select and dispose the metallic wiring layer 270 of the above-mentioned embodiment (FIG. 4) according to the application need so as to achieve the required technical effect and effectively advance the application and flexibility of the package structure.

In summary, the dielectric layer of the invention has flexible property and can extend from the main mounting surface of the carrier up, along boundaries between the main mounting surface and the side mounting surfaces, onto the side mounting surfaces, so that the package carrier of the invention can be bent to form a three-dimensional package carrier through the flexible property of the dielectric layer. Further, since the heat-generating elements of the invention are located on a portion of the main mounting surface and portions of the side mounting surfaces of the carrier exposed by the first openings of the dielectric layer of the package carrier and the heat-generating elements are electrically connected to the surface treatment layer of the package carrier through the bonding wires, so that the package structure of the invention can have light-emitting effect with three-dimensional polyhedron. In addition, the heat of the heat-generating elements of the invention can be directly and fast transmitted outwards through the carrier, so that the package structure of the invention has better heat-dissipating effect. In addition, a user can dispose the metallic wiring layer on the dielectric layer so as to connect in series, in parallel or in series-and-parallel the heat-generating elements located on the main mounting surface and the side mounting surface by oneself according to the application need, which can advance the application and the flexibility of the package structure.

It will be apparent to those skilled in the art that the descriptions above are several preferred embodiments of the invention only, which does not limit the implementing range of the invention. Various modifications and variations can be made to the structure of the invention without departing from the scope or spirit of the invention. The claim scope of the invention is defined by the claims hereinafter.

What is claimed is:

1. A package carrier, comprising
a carrier, having a main mounting surface and at least two side mounting surfaces connecting the main mounting surface;
a dielectric layer, disposed on the carrier and having a plurality of first openings, wherein the dielectric layer extends from the main mounting surface up, along boundaries between the main mounting surface and the side mounting surfaces, onto the side mounting surfaces, and the first openings expose a portion of the main mounting surface and portions of the side mounting surfaces;
a metal layer, disposed on the dielectric layer and having a plurality of second openings and a plurality of third openings, wherein the second openings are disposed correspondingly to the first openings, and the third openings expose a portion of the dielectric layer located at the boundaries between the main mounting surface and the side mounting surfaces;
a surface treatment layer, disposed on a portion of the metal layer; and
a solder resist layer, disposed on a portion of the metal layer and a portion of the dielectric layer both are exposed out of the surface treatment layer.

2. The package carrier as claimed in claim 1, wherein the carrier comprises a heat sink, a heat-dissipating fin, a thermal tube or a vapor chamber heat block.

3. The package carrier as claimed in claim 1, wherein the carrier comprises a supporting element and a heat-conductive layer, the supporting element has the main mounting surface and the side mounting surfaces, the heat-conductive layer covers the main mounting surface and the side mounting surfaces, and the first openings of the dielectric layer expose a portion of the heat-conductive layer.

4. The package carrier as claimed in claim 3, wherein the supporting element comprises a plastic supporting frame, a heat sink, a heat-dissipating fin, a thermal tube or a vapor chamber heat block.

5. The package carrier as claimed in claim 3, further comprising a first adhesive layer disposed between the heat-conductive layer and the dielectric layer, wherein the first adhesive layer extends from the heat-conductive layer located on the main mounting surface up, along an upper place of the boundaries between the main mounting surface and the side mounting surfaces, onto the heat-conductive layer located on the side mounting surfaces.

6. The package carrier as claimed in claim 3, wherein the carrier further comprises a laminated structure disposed between the heat-conductive layer and the supporting element, the laminated structure comprises a second adhesive layer, a first conductive layer, a second conductive layer, an insulation layer and a plurality of conductor pillars, the second adhesive layer is disposed between the first conductive layer and the heat-conductive layer, the insulation layer is located between the first conductive layer and the second conductive layer and has a plurality of through holes, and the conductor pillars are respectively disposed in the through holes and connected to the first conductive layer and the second conductive layer.

7. The package carrier as claimed in claim 1, further comprising an adhesive layer disposed between the carrier and the dielectric layer, wherein the adhesive layer extends from the main mounting surface of the carrier up, along the boundaries between the main mounting surface and the side mounting surfaces, onto the side mounting surfaces.

8. A package structure, comprising:
a package carrier, comprising:
a carrier, having a main mounting surface and at least two side mounting surfaces connecting the main mounting surface;
a dielectric layer, disposed on the carrier and having a plurality of first openings, wherein the dielectric layer extends from the main mounting surface up, along boundaries between the main mounting surface and the side mounting surfaces, onto the side mounting surfaces, and the first openings expose a portion of the main mounting surface and portions of the side mounting surfaces;
a metal layer, disposed on the dielectric layer and having a plurality of second openings and a plurality of third openings, wherein the second openings are disposed correspondingly to the first openings, and the third openings expose a portion of the dielectric layer located at the boundaries between the main mounting surface and the side mounting surfaces;
a surface treatment layer, disposed on a portion of the metal layer; and
a solder resist layer, disposed on a portion of the metal layer and a portion of the dielectric layer both are exposed out of the surface treatment layer;
a plurality of heat-generating elements, disposed on the package carrier and located on a portion of the main mounting surface and portions of the side mounting surfaces exposed by the first openings;
a plurality of bonding wires, electrically connected to the heat-generating elements and the package carrier; and
a plurality of package bodies, encapsulating the heat-generating elements, the bonding wires and a portion of the package carrier and exposing a portion of the solder resist layer and a portion of the dielectric layer located on boundaries between the main mounting surface and the side mounting surfaces.

9. The package structure as claimed in claim 8, wherein the electrical connection between the heat-generating elements and the package carrier comprises connection in series, connection in parallel or connection in series-and-parallel.

10. The package structure as claimed in claim 8, wherein the carrier comprises a heat sink, a heat-dissipating fin, a thermal tube or a vapor chamber heat block.

11. The package structure as claimed in claim 8, wherein the carrier comprises a supporting element and a heat-conductive layer, the supporting element has the main mounting surface and the side mounting surfaces, the heat-conductive layer covers the main mounting surface and the side mounting surfaces, and the first openings of the dielectric layer expose a portion of the heat-conductive layer.

12. The package structure as claimed in claim 11, wherein the supporting element comprises a plastic supporting frame, a heat sink, a heat-dissipating fin, a thermal tube or a vapor chamber heat block.

13. The package structure as claimed in claim 11, wherein the package carrier further comprises a first adhesive layer disposed between the heat-conductive layer and the dielectric layer, the first adhesive layer extends from the heat-conductive layer located on the main mounting surface up, along an upper place of the boundaries between the main mounting surface and the side mounting surfaces, onto the heat-conductive layer located on the side mounting surfaces.

14. The package structure as claimed in claim 11, wherein the carrier further comprises a laminated structure disposed between the heat-conductive layer and the supporting element, the laminated structure comprises a second adhesive layer, a first conductive layer, a second conductive layer, an insulation layer and a plurality of conductor pillars, the second adhesive layer is disposed between the first conductive layer and the heat-conductive layer, the insulation layer is located between the first conductive layer and the second conductive layer and has a plurality of through holes, and the conductor pillars are respectively disposed in the through holes and connected to the first conductive layer and the second conductive layer.

15. The package structure as claimed in claim 8, wherein the package carrier further comprises an adhesive layer disposed between the carrier and the dielectric layer, the adhesive layer extends from the main mounting surface of the carrier up, along the boundaries between the main mounting surface and the side mounting surfaces, onto the side mounting surfaces.
